(19) United States
(12) Patent Application Publication
(10) Pub. No.: US 2026/0362740 A1
(43) Pub. Date: Nov. 12, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Hiroki WAKIMOTO, Matsumoto-city (JP); Ryutaro ISHIZAKI, Matsumoto-city (JP)

(73) Assignee: FUJI ELECTRIC CO., LTD., Kawasaki-shi (JP)

(21) Appl. No.: 19/723,897

(22) Filed: Jun. 29, 2026

Related U.S. Application Data
(63) Continuation of application No. PCT/JP2025/020823, filed on Jun. 9, 2025.

(30) Foreign Application Priority Data
Jul. 4, 2024 (JP) 2024-108222

(51) Int. Cl. H10D 30/66; H10D 30/01

(52) U.S. Cl. CPC H10D 30/665; H10D 30/0291; H10D 30/668

(57) ABSTRACT

A semiconductor device has an active region through which a current flows, and a termination structure portion disposed outside the active region and in which a voltage withstanding structure surrounding a periphery of the active region is provided. In the termination structure portion, the silicon semiconductor substrate contains antimony as an n-type dopant, a first semiconductor region of an n-type is provided in the semiconductor substrate, at a front surface thereof, and a second semiconductor region of a p-type is selectively provided in the silicon semiconductor substrate, at the front surface thereof. A dopant concentration of the first semiconductor region is lower than a dopant concentration of the second semiconductor region and is no lower than a dopant concentration of the bulk region of the semiconductor substrate, at a back surface of the semiconductor substrate.

### CROSS REFERENCE TO RELATED APPLICATIONS

This is a continuation application of International Application PCT/JP2025/020823 filed on Jun. 9, 2025 which claims priority from a Japanese Patent Application No. 2024-108222 filed on Jul. 4, 2024, the contents of which are incorporated herein by reference.

### BACKGROUND OF THE INVENTION

### 1. Field of the Invention

Embodiments of the disclosure relate to a semiconductor device and a method of manufacturing a semiconductor device.

### 2. Description of the Related Art

Conventionally, a semiconductor device having a silicon (Si) substrate in which antimony (Sb) is used as an n-type dopant material is known. For example, refer to Japanese Laid-Open Patent Publication No. 2020-074381 and Japanese Laid-Open Patent Publication No. 2017-063187.

### SUMMARY OF THE INVENTION

According to the present disclosure, a semiconductor device, includes: a silicon semiconductor substrate having an active region through which a current flows and a termination structure portion disposed outside the active region and having formed therein, a voltage withstanding structure surrounding, in a plan view of the semiconductor device, a periphery of the active region, the silicon semiconductor substrate containing antimony as an n-type dopant in the termination structure portion, the silicon semiconductor substrate having a first main surface and a second main surface opposite to each other, and a bulk region at the second main surface; a first semiconductor region of an n-type, provided in the silicon semiconductor substrate, at the first main surface thereof in the termination structure portion; and a second semiconductor region of a p-type selectively provided in the silicon semiconductor substrate, at the first main surface thereof in the termination structure portion. A dopant concentration of the first semiconductor region is lower than a dopant concentration of the second semiconductor region, and is no lower than a dopant concentration of the bulk region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 2 is a graph depicting the distribution of an n-type dopant concentration of the semiconductor device according to the embodiment.

FIG. 3 is a graph depicting a distribution of an n-type dopant concentration of a conventional semiconductor device.

### DETAILED DESCRIPTION OF THE INVENTION

First, problems associated with conventional techniques are discussed. In a conventional semiconductor device in which Sb is used as an n-type dopant material, a problem arises in that the n-type dopant concentration at the surface of the Si substrate decreases.

An outline of an embodiment of the present disclosure is described. A semiconductor device according to the present disclosure has the following features. A silicon semiconductor substrate having an active region through which a current flows and a termination structure portion disposed outside the active region and having formed therein, a voltage withstanding structure surrounding, in a plan view of the semiconductor device, a periphery of the active region, the silicon semiconductor substrate containing antimony as an n-type dopant in the termination structure portion, the silicon semiconductor substrate having a first main surface and a second main surface opposite to each other, and a bulk region at the second main surface; a first semiconductor region of an n-type, provided in the silicon semiconductor substrate, at the front surface thereof in the termination structure portion; and a second semiconductor region of a p-type selectively provided in the silicon semiconductor substrate, at the first main surface thereof in the termination structure portion. A dopant concentration of the first semiconductor region is lower than a dopant concentration of the second semiconductor region and a same as or higher than a dopant concentration of the bulk region.

According to the disclosure above, the n-type dopant concentration of the semiconductor substrate, at the front surface thereof may be stably controlled, whereby the dopant concentration of the semiconductor substrate, at the front surface thereof is not affected by the amount of Sb taken into the thermal oxide film. Thus, a power semiconductor for which the breakdown voltage characteristics and the long-term reliability are stabilized may be provided.

Further, in the semiconductor device according to the present disclosure, in the disclosure above, phosphorous, antimony, or arsenic, or a combination thereof is doped in the first semiconductor region.

Further, in the semiconductor device according to the present disclosure, in the disclosure above, the dopant concentration of the first semiconductor region is within −5% to +5% of the dopant concentration of the bulk region.

Further, in the semiconductor device according to the present disclosure, in the disclosure above, the dopant concentration of the first semiconductor region is 10% to 20% higher than the dopant concentration of the bulk region.

Further, in the semiconductor device according to the present disclosure, in the disclosure above, the first semiconductor region has a thickness not less than 5.0 μm but not more than 12.0 μm.

A method of manufacturing a semiconductor device according to the present disclosure has the following features and is a method of manufacturing a semiconductor device having an active region through which a current flows and a termination structure portion disposed outside the active region and in which a voltage withstanding structure surrounding a periphery of the active region is formed. In the termination structure portion, a silicon semiconductor substrate contains antimony as an n-type dopant and the method includes a first process of forming in the termination structure portion, a first semiconductor region of an n-type in the silicon semiconductor substrate, at a front surface thereof; and a second process of selectively forming in the termination structure portion, a second semiconductor region of a p-type in the silicon semiconductor substrate, at the front surface thereof. In the first process, the first semiconductor region is formed to have a dopant concentration that is a same as or higher than a dopant concentration of a bulk region of the silicon semiconductor substrate, the bulk region being relatively closer to the back surface of the silicon semiconductor substrate than is the second semiconductor region.

Findings underlying the present disclosure are discussed. First, problems associated with the conventional semiconductor device are discussed. Conventionally, when Sb is used as an n-type dopant material, due to thermal oxidation, Sb is easily taken up into the thermal oxide film and when the semiconductor device is completed, the n-type dopant concentration at the surface of the Si substrate tends to be relatively lower.

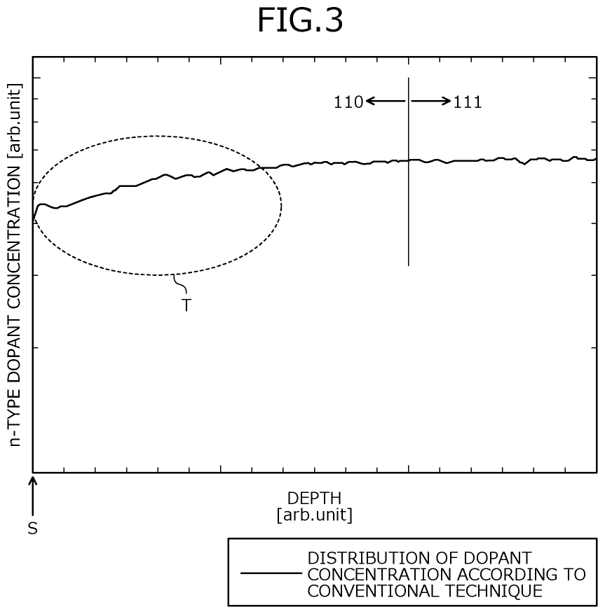

FIG. 3 is a graph depicting a distribution of the n-type dopant concentration of a conventional semiconductor device. In FIG. 3, a vertical axis represents the n-type dopant concentration and a horizontal axis represents depth from the surface of the Si substrate, while a position S indicates the surface of the Si substrate. FIG. 3 depicts the distribution of the n-type dopant concentration in a vicinity of the surface of the Si substrate of the conventional semiconductor device fabricated with a Si substrate in which Sb is used as an n-type dopant.

As depicted in FIG. 3, in a vicinity T of the surface of the Si substrate, Sb is taken up by the thermal oxide film whereby the n-type dopant concentration is about 30% lower than the n-type dopant concentration in a bulk region 111 of the substrate. The amount of decrease of the n-type dopant concentration of the Si substrate, at the surface thereof, is determined by the amount of Sb taken up by the thermal oxide film and thus, is affected by the thickness of the thermal oxide film, variation of heat treatment conditions during wafer processing, etc., whereby the amount of decrease of the n-type dopant concentration of the Si substrate, at the surface thereof easily becomes unstable. The n-type dopant concentration of the Si substrate, at the surface thereof affects the electric field distribution of a voltage withstanding structure portion of the semiconductor device and thus, a problem arises in that charge resistance related to breakdown voltage characteristics and long-term reliability of the semiconductor device varies.

Embodiments of a semiconductor device and a method of manufacturing a semiconductor device according to the present disclosure will be described in detail with reference to the accompanying drawings. In the present description and accompanying drawings, layers and regions prefixed with n or p mean that majority carriers are electrons or holes. Additionally, +or − appended to n or p means that the dopant concentration is higher or lower, respectively, than layers and regions without +or −. In the description of the embodiments below and the accompanying drawings, main portions that are identical will be given the same reference numerals and will not be repeatedly described. Further, with consideration of variation in manufacturing, description indicating the “same” or “equal” may be within 5%.

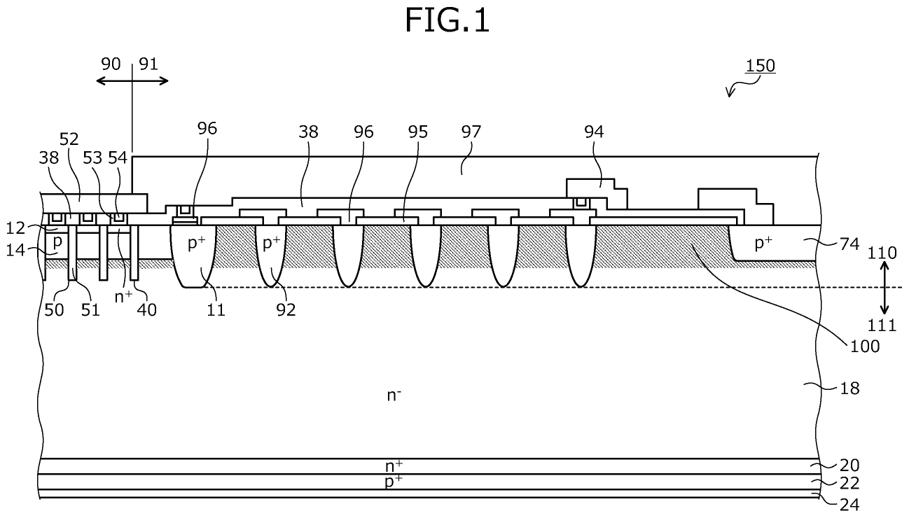

A structure of the semiconductor device according to the embodiment is described taking an insulated gate bipolar transistor (IGBT) as an example. FIG. 1 is a cross-sectional view depicting a structure of the semiconductor device according to the embodiment. The semiconductor device according to the embodiment depicted in FIG. 1 is an IGBT 150 having a trench gate structure.

The IGBT 150 has an active region 90 and an edge termination region 91 surrounding a periphery of the active region 90. The active region 90 is a region through which a current flows during an on-state. The edge termination region 91 includes in a front portion thereof facing a front surface of a semiconductor chip, a breakdown voltage maintaining region that relaxes electric field of a drift region,. A border between the active region 90 and the edge termination region 91 is a center of a gate trench 40 having only on one side thereof, a later-described n⁺-type emitter region 12.

In an n⁻-type semiconductor substrate (silicon semiconductor substrate) 18, at a front surface (first main surface) thereof, an n-type accumulation layer may be provided; the n⁻-type semiconductor substrate 18 constitutes an n⁻-type drift layer of the active region 90. A later-described n-type dopant region 100 may constitute the n-type accumulation layer. The n-type accumulation layer may be omitted. The n⁻-type semiconductor substrate 18 is a Si substrate in which Sb is used as an n-type dopant material. Above the n-type accumulation layer (side thereof facing the front surface of the n⁻-type semiconductor substrate 18), a p-type base region 14 is provided. The p-type base region 14 functions as a channel region in the IGBT 150. Gate trenches 40 that penetrate through the p-type base region 14 and reach the n⁻-type semiconductor substrate 18 are provided. The gate trenches 40, for example, are disposed at predetermined intervals in a striped pattern in a plan view, thereby dividing the p-type base region 14 into multiple regions (mesa portions), and each of the gate trenches 40 has on each side thereof facing an adjacent gate trench 40, an n⁺-type emitter region 12. In each of the gate trenches 40, a gate insulating film 50 is provided along an inner wall of the gate trench 40 and a gate electrode 51 is provided on the gate insulating film 50.

In the p-type base region 14, in each of the mesa portions thereof, the n⁺-type emitter regions 12 are selectively provided. The n⁺-type emitter regions 12 face the gate electrodes 51 with the gate insulating films 50 provided in the gate trenches 40, respectively, intervening therebetween. An emitter electrode 52 is in contact with the n⁺-type emitter regions 12 via contact holes and is electrically insulated from the gate electrodes 51 via an interlayer insulating film 38. In the n⁺-type emitter regions 12, openings are selectively provided and in the openings, the emitter electrode 52 and the p-type base region 14 may be electrically connected. Between the emitter electrode 52 and the interlayer insulating film 38, for example, a barrier metal 53 that prevents diffusion of metal atoms from the emitter electrode 52 toward the gate electrode 51 may be provided.

Further, contact electrodes 54 may be embedded in the contact holes formed in the interlayer insulating film 38. The contact electrodes 54 are, for example, metal films containing, as a material, tungsten (W), which has high embeddability. On the emitter electrode 52, for example, a protective film 97 such as a passivation film containing polyimide is selectively provided.

In the n⁻-type semiconductor substrate 18, at a back surface (second main surface) thereof, an n⁺-type field stop (FS) layer 20 is provided. The n+-type FS layer 20 has a function of suppressing the spreading of a depletion layer that spreads toward a later-described p⁺-type collector region 22, from pn junctions between the p-type base region 14 and the n⁻-type semiconductor substrate 18 during an off-state.

In the n⁻-type semiconductor substrate 18, at the back surface thereof, at a shallow position closer to the back surface of the n⁻-type semiconductor substrate 18 than is the n⁺-type FS layer 20, the p⁺-type collector region 22 is provided. A back electrode 24 is provided at a surface (entire back surface of the n⁻-type semiconductor substrate 18) of the p⁺-type collector region 22. The back electrode 24 functions as a collector electrode.

In the edge termination region 91, a field oxide film 95 is provided at the front surface of the n⁻-type semiconductor substrate 18 and a conductive film 96 is provided on the field oxide film 95. The conductive film 96 may be a polycrystalline silicon film. The interlayer insulating film 38 is provided over the n⁻-type semiconductor substrate 18 and the conductive film 96. A field plate electrode 94 is provided on the conductive film 96. The field plate electrode 94 may be in contact with the conductive film 96 via a contact hole provided in the interlayer insulating film 38 and may be insulated from the n⁻-type semiconductor substrate 18 by the field oxide film 95. Between the field plate electrode 94 and the interlayer insulating film 38, for example, the barrier metal 53 that prevents diffusion of metal atoms from the field plate electrode 94 toward the conductive film 96 may be provided. Further, the contact electrodes 54 may be embedded in the contact holes formed in the interlayer insulating film 38. The contact electrodes 54 are, for example, metal films containing, as a material, tungsten (W), which has high embeddability.

In the edge termination region 91, toward the active region 90, a p+-type well region 11 is provided. In the edge termination region 91, a guard ring (second semiconductor region of a p-type) 92 of a p⁺-type and a channel stopper 74 of a p⁺-type and in contact with the chip end are provided. Further, the channel stopper 74 may be an n-type. The guard ring 92 may be provided in plural. FIG. 1 depicts an example when the guard ring 92 is provided in plural.

The guard ring 92 may be provided in the edge termination region 91, so as to surround the active region 90 in a plan view. When the guard ring 92 is provided in plural, the guard rings 92 may have the same dopant concentration. The conductive film 96 is provided on the guard ring 92 and the guard ring 92 is in contact with the conductive film 96 via contact holes formed in the field oxide film 95. Further, the field plate electrode 94 is provided at an upper surface of the interlayer insulating film 38 so as to be in contact with the surfaces of the channel stopper 74 and the guard ring 92. On the interlayer insulating film 38 and the field plate electrode 94, for example, the protective film 97 constituted by a passivation film containing a polyimide or the like is provided. In the edge termination region 91, at the back surface thereof, the p⁺-type collector region 22 and the n⁺-type FS layer 20 are provided.

In the embodiment, in the edge termination region 91, the n-type dopant region (first semiconductor region of an n-type) 100 is in the n⁻-type semiconductor substrate 18, at the front surface thereof. During wafer processing, the n-type dopant region 100 is formed by doping an n-type dopant such as phosphorus (P), arsenic (As), or Sb, or a combination thereof at the front surface of the n⁻-type semiconductor substrate 18 and then, activating and diffusing the n-type dopant by a heat treatment. The n-type dopant region 100 may be formed so as to compensate the dopant concentration of the n⁻-type semiconductor substrate 18 in which the n-type dopant concentration decreases as a result of the uptake of Sb in the thermal oxide film. When the n-type dopant region 100 is deeper than the p⁺-type well region 11, the breakdown voltage may decrease and therefore, preferably, the n-type dopant region 100 may be shallower than the p⁺-type well region 11. The n-type dopant region 100 may be formed to be continuous from the edge termination region 91 to the active region 90. By being continuous to the active region 90, the n-type dopant region 100 may act as a so-called n-type accumulation layer and the concentration may be suitably set, whereby the on-voltage may be reduced without reduction of the breakdown voltage. Further, the n-type dopant region 100 may be formed so that the active region 90 is free of the n-type dopant region 100. The active region 90 being free of the n-type dopant region 100 eliminates concern of the breakdown voltage decreasing.

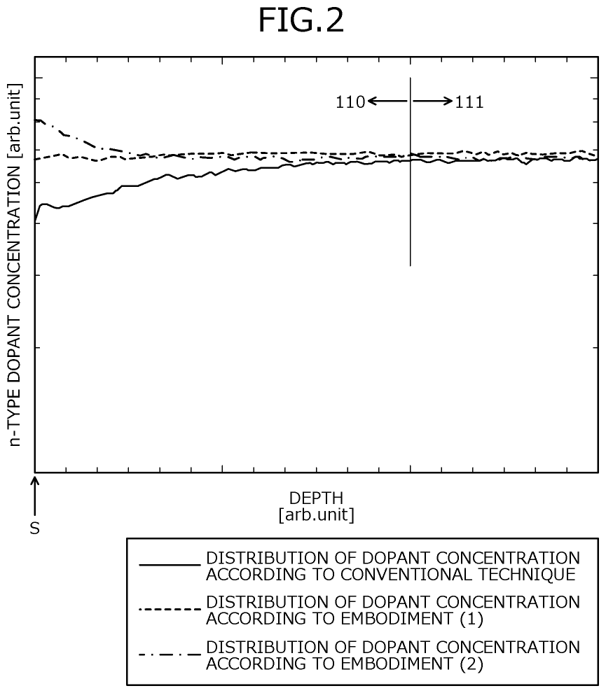

FIG. 2 is a graph depicting the distribution of the n-type dopant concentration of the semiconductor device according to the embodiment. In FIG. 2, a vertical axis represents the n-type dopant concentration and a horizontal axis represents depth from the front surface of the n⁻-type semiconductor substrate 18, while the position S indicates an outermost surface of the front surface of the n⁻-type semiconductor substrate 18. FIG. 2 depicts the distribution of the n-type dopant concentration in the embodiment and conventionally, near the surface of the Si substrate in a semiconductor device fabricated using Sb as an n-type dopant in the Si substrate. In FIG. 2, a substrate surface region 110 is a region of the n⁻-type semiconductor substrate 18, where the p⁺-type well region 11 is provided while a bulk region 111 is a region of the n⁻-type semiconductor substrate 18, closer to the back surface thereof (surface thereof facing the back electrode 28) than is the p⁺-type well region 11.

As depicted in FIG. 2, the dopant concentration of the substrate surface region 110 of the n⁻-type semiconductor substrate 18 is assumed to be equal to or greater than the dopant concentration of the bulk region 111 of the n⁻-type semiconductor substrate 18. In FIG. 2, a dot-dash chained line (2) represents an instance in which the dopant concentration of the substrate surface region 110 is a concentration equal to or greater than the dopant concentration of the bulk region 111. For example, the dopant concentration of the substrate surface region 110 is 10% to 20% higher than the dopant concentration of the bulk region 111. In FIG. 2, a dashed line (1) represents an instance in which the dopant concentration of the substrate surface region 110 is a concentration equal to the dopant concentration of the bulk region 111. For example, the dopant concentration of the substrate surface region 110 is within −5% to +5% of the dopant concentration of the bulk region 111.

Here, when the dopant concentration of the substrate surface region 110 is higher than the dopant concentration of the bulk region 111, spreading of a depletion layer in the edge termination region 91 is difficult and the breakdown voltage decreases more than when the dopant concentration of the substrate surface region 110 is equal to the dopant concentration of the bulk region 111. Thus, characteristics of the semiconductor device are improved when the dopant concentration of the substrate surface region 110 is equal to the dopant concentration of the bulk region 111. However, making the dopant concentration of the substrate surface region 110 equal to the dopant concentration of the bulk region 111 makes adjustment of the dopant concentration of the substrate surface region 110 difficult to stabilize, thereby making manufacturing difficult.

As described, in the n⁻-type semiconductor substrate 18 containing Si and using Sb, the n-type dopant region 100 is provided at the front surface of the n⁻-type semiconductor substrate 18. As a result, the n-type dopant concentration of the n⁻-type semiconductor substrate 18, at the front surface thereof may be stably controlled and the dopant concentration of the n⁻-type semiconductor substrate 18, at the front surface thereof is not affected by the amount of Sb taken in by the thermal oxide film (the field oxide film 95). Thus, a power semiconductor having stabilized long-term reliability and breakdown voltage characteristics may be provided. When the dopant concentration of the substrate surface region 110 is 10% to 20% higher than the dopant concentration of the bulk region 111, the breakdown voltage characteristics and the long-term reliability are more stable and preferable than when the dopant concentration of the substrate surface region 110 is within −5% to +5% the dopant concentration of the bulk region 111.

Next, a method of manufacturing the semiconductor device according to the embodiment is described. For example, manufacturing is as follows. First, the gate trenches 40, the gate insulating films 50, and the gate electrodes 51 are sequentially formed by a general method in the n⁻-type semiconductor substrate 18, at the front surface thereof; the n⁻-type semiconductor substrate 18 constitutes an n-type drift layer of the active region 90. In the n⁻-type semiconductor substrate 18, at the front surface thereof, at a shallow depth closer to the front surface of the n⁻-type semiconductor substrate 18 than are bottoms of the gate trenches 40, for example, the n-type accumulation layer may be formed by ion implantation or epitaxial growth.

Next, the n⁻-type semiconductor substrate 18 is doped with an n-type dopant such as P, As, Sb, etc., at a front surface thereof. P, As, Sb, or the like may be doped individually or in combination. Thereafter, the n-type dopant is activated by a heat treatment and diffused, whereby the n-type dopant region 100 is formed in the n⁻-type semiconductor substrate 18, at the front surface thereof in the edge termination region 91. In the formation of the n-type dopant region 100, first, in the n⁻-type semiconductor substrate 18, at the front surface thereof, an n-type dopant may be doped by an ion implantation method and diffused before formation of the n-type accumulation layer and MOS gates of the active region 90.

Further, as described above, Sb is easily taken into the thermal oxide film (the field oxide film 95). For example, as depicted in FIG. 3, at the front surface of the n⁻-type semiconductor substrate 18, the dopant concentration decreases about 30%. Thus, when the dopant concentration of the substrate surface region 110 is to be equal to the dopant concentration of the bulk region 111, the n-type dopant is doped so that the dopant concentration of the substrate surface region 110 is about 30% higher than the dopant concentration of the bulk region 111. In this case, Sb is taken into the thermal oxide film and thus, after formation of the thermal oxide film, the dopant concentration of the substrate surface region 110 becomes equal to the dopant concentration of the bulk region 111. Similarly, when the dopant concentration of the substrate surface region 110 is to be higher than the dopant concentration of the bulk region 111, the n-type dopant is doped so that the dopant concentration of the substrate surface region 110 becomes 30% higher than the dopant concentration of the bulk region 111. Further, P diffuses more easily than As and thus, preferably P may be used as the n-type dopant. When As is used, diffusion is difficult and thus, preferably the doping amount thereof may be higher than that for P.

Next, in the edge termination region 91, the field oxide film 95 is formed at the front surface of the n⁻-type semiconductor substrate 18 by thermal oxidation. Next, in the edge termination region 91, the field oxide film 95 is patterned and used as a mask to ion-implant a p-type dopant such as boron (B) and thereby selectively form the p⁺-type well region 11, the guard ring 92, and the channel stopper 74 in the n⁻-type semiconductor substrate 18, at the front surface thereof.

Next, in the active region 90 and in the edge termination region 91, closer to the active region 90 than is the p⁺-type well region 11, a p-type dopant such as boron (B) is ion-implanted thereby forming the p-type base region 14 at a shallower depth from the front surface of the n⁻-type semiconductor substrate 18 than are bottoms of the gate trenches 40. Alternatively, in an instance in which the n-type accumulation layer is provided, the p-type base region 14 is formed at a shallower depth from the front surface of the n⁻-type semiconductor substrate 18 than is the n-type accumulation layer.

Next, an n-type dopant such as phosphorous (P) or arsenic (As) is ion-implanted thereby selectively forming the n⁺-type emitter regions 12 in the p-type base region 14. Next, for example, the interlayer insulating film 38, such as a BPSG film, is deposited (formed) so as to cover the gate electrodes 51.

Next, the interlayer insulating film 38 is patterned and contact holes are formed thereby exposing the n⁺-type emitter regions 12 while in the edge termination region 91, the channel stopper 74, the p⁺-type well region 11, and the guard ring 92 are exposed. Next, in the contact holes, the contact electrodes 54 are formed via the barrier metal 53. Next, for example, the emitter electrode 52 covering an entire area of the surface of the interlayer insulating film 38 is formed by a sputtering method, so as to be in contact with the contact electrodes 54 in the contact holes. In the edge termination region 91, for example, the field plate electrode 94 partially covering the surface of the interlayer insulating film 38 is formed by a sputtering method, so as to be in contact with the contact electrodes 54 in contact holes. Further, the contact electrodes 54 may be omitted and in this instance, the emitter electrode 52 may be embedded in the contact holes. The emitter electrode 52 and the field plate electrode 94 may be formed concurrently or may be formed separately. As described, device structures of the front surface of the semiconductor device according to the embodiment are formed.

Next, the n⁻-type semiconductor substrate 18 is ground from the back surface thereof to a position corresponding to a product thickness used for the semiconductor device. Next, at the entire back surface of the n⁻-type semiconductor substrate 18, for example, a p-type dopant such as boron (B) is ion-implanted thereby forming the p⁺-type collector region 22 in the n⁻-type semiconductor substrate 18, at the entire back surface thereof. Next, at the entire back surface of the n⁻-type semiconductor substrate 18, for example, an n-type dopant such as phosphorous or protons are ion-implanted thereby forming the n⁺-type FS layer 20 in the n⁻-type semiconductor substrate 18. The n⁺-type FS layer 20 may be formed before the p⁺-type collector region 22.

Next, the p⁺-type collector region 22 and the n⁺-type FS layer 20 are activated by a heat treatment (annealing). Next, the entire front surface of the n⁻-type semiconductor substrate 18 is covered by, for example, a surface protective film (not depicted) such as a polyimide film and thereafter, the surface protective film is patterned thereby exposing the emitter electrode 52 and each electrode pad.

Next, at the entire back surface of the n⁻-type semiconductor substrate 18, the back electrode 24 in contact with the p⁺-type collector region 22 is formed. Thereafter, the semiconductor wafer is cut (diced) into individual chips, whereby the IGBT 150 depicted in FIG. 1 is completed.

As described above, according to the embodiment, the n⁻-type semiconductor substrate contains Si and uses Sb; and in the n⁻-type semiconductor substrate, at the front surface thereof, an n-type dopant is doped by an ion implantation method and a heat treatment is performed, thereby providing the n-type dopant region. As a result, the n-type dopant concentration of the n⁻-type semiconductor substrate, at the front surface may be stably controlled and the dopant concentration of the n⁻-type semiconductor substrate, at the front surface thereof is not affected by the amount of Sb taken in by the thermal oxide film. Thus, a power semiconductor for which the breakdown voltage characteristics and the long-term reliability are stabilized may be provided.

In the foregoing, the present disclosure may be variously modified in a range not departing from the spirit of the disclosure and in the embodiments described above, for example, dimensions, dopant concentrations, etc. may be variously set according to necessary specifications. Further, in the embodiments of the present disclosure, while a trench-type IGBT is described as an example, without limitation hereto, the present disclosure is further applicable to semiconductor devices of various configurations such as a planar-type IGBT, a metal oxide semiconductor (MOS) semiconductor device like an insulated-gate metal oxide semiconductor field effect transistor (MOSFET), and the like.

According to the disclosure above, the n-type dopant concentration of a semiconductor substrate, at the front surface thereof may be stably controlled while the dopant concentration of the semiconductor substrate, at the front surface thereof is not affected by the amount of Sb taken up by the thermal oxide film. Thus, a power semiconductor for which the breakdown voltage characteristics and the long-term reliability are stabilized may be provided.

The semiconductor device and the method of manufacturing a semiconductor device according to the present disclosure achieve an effect in that when Sb is used an n-type dopant material, decrease of the n-type dopant concentration of the Si substrate, at the surface thereof may be prevented.

As described, the semiconductor device and the method of manufacturing a semiconductor device according to the present disclosure is useful for power semiconductor devices used for power converting equipment such as that for inverters, power source devices of various industrial machines, igniters of vehicles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a silicon semiconductor substrate having
an active region through which a current flows and
a termination structure portion disposed outside the active region and having formed therein, a voltage withstanding structure surrounding, in a plan view of the semiconductor device, a periphery of the active region,
the silicon semiconductor substrate containing antimony as an n-type dopant in the termination structure portion, the silicon semiconductor substrate having a first main surface and a second main surface opposite to each other, and a bulk region at the second main surface;
a first semiconductor region of an n-type, provided in the silicon semiconductor substrate, at the first main surface thereof in the termination structure portion; and
a second semiconductor region of a p-type selectively provided in the silicon semiconductor substrate, at the first main surface thereof in the termination structure portion, wherein
a dopant concentration of the first semiconductor region is lower than a dopant concentration of the second semiconductor region, and is no lower than a dopant concentration of the bulk region.

2. The semiconductor device according to claim 1, wherein the first semiconductor region is doped with phosphorous, antimony, arsenic, or a combination thereof.

3. The semiconductor device according to claim 1, wherein the dopant concentration of the first semiconductor region is within −5% to +5% of the dopant concentration of the bulk region.

4. The semiconductor device according to claim 1, wherein the dopant concentration of the first semiconductor region is 10% to 20% higher than the dopant concentration of the bulk region.

5. The semiconductor device according to claim 1, wherein the first semiconductor region has a thickness not less than 5.0 μm but not more than 12.0 μm.

6. The semiconductor device according to claim 1, wherein the first semiconductor region is shallower than the second semiconductor region.

7. A method of manufacturing a semiconductor device, the method comprising:
preparing a silicon semiconductor substrate having
an active region through which a current flows, and
a termination structure portion disposed outside the active region and having formed therein a voltage withstanding structure surrounding, in a plan view of the semiconductor device, a periphery of the active region,
the silicon semiconductor substrate containing antimony as an n-type dopant in the termination structure portion, the silicon semiconductor substrate having a first main surface and a second main surface opposite to each other, and a bulk region at the second main surface;
forming, in the termination structure portion, a first semiconductor region of an n-type in the silicon semiconductor substrate, at the first main surface thereof; and
selectively forming, in the termination structure portion, a second semiconductor region of a p-type in the silicon semiconductor substrate, at the first main surface thereof, wherein
the first semiconductor region is formed having a dopant concentration that is lower than a dopant concentration of the second semiconductor region and higher than a dopant concentration of the bulk region.

8. The method according to claim 7, wherein the first semiconductor region is formed shallower than is the second semiconductor region.
